(19) United States
(12) Patent Application Publication
(10) Pub. No.: US 2010/0022040 A1
(43) Pub. Date: Jan. 28, 2010

(54) METHOD FOR PRODUCING LIGHT-EMITTING DEVICE

(76) Inventors: Masahiro Konishi, Osaka-shi (JP); Masayuki Ohta, Osaka-shi (JP); Yutaka Okada, Osaka-shi (JP); Yoshifumi Inada, Osaka-shi (JP)

Correspondence Address: NIXON & VANDERHYE, PC, 901 NORTH GLEBE ROAD, 11TH FLOOR, ARLINGTON, VA, 22203, US

(21) Appl. No.: 12/507,417

(22) Filed: Jul. 22, 2009

(30) Foreign Application Priority Data
Jul. 23, 2008 (JP) 2008-189922

(51) Int. Cl. H01L 33/00

(52) U.S. Cl. 438/29; 257/E33.061; 257/E33.067

(57) ABSTRACT

[Object] To restrain color variation in light emitted from a light-emitting device.

[Means to achieve the object] A method for producing a light-emitting device includes the steps of: (a) die-bonding a chip onto a substrate so as to prepare a die-bonded substrate; (b) preparing a mold having a cavity; (c) setting the die-bonded substrate such that the chip is placed in the cavity; and (d) injecting sealing resin into the cavity via a runner section. In the method, the runner section is capable of maintaining its temperature at a low temperature lower than a temperature of the mold and the step (d) injecting the sealing resin that is maintained at the low temperature in the runner section, into the cavity via the runner section.

This Nonprovisional application claims priority under 35 U.S.C. §119(a) on Patent Application No. 2008-189922 filed in Japan on Jul. 23, 2008 the entire contents of which are hereby incorporated by reference.

### TECHNICAL FIELD

The present invention relates to a method for producing a light-emitting device, which method includes resin sealing.

### BACKGROUND ART

As a method for producing a light-emitting device (i) which includes a light-emitting element (chip) and a fluorescent material, and (ii) which emits white light obtained from blue light emitted from the light-emitting element and fluorescent light emitted from the fluorescent material which emits the fluorescent light by absorbing the blue light, there is a method in which a resin pellet made of a curable silicone resin composition containing the fluorescent material is transfer-molded so as to cover a chip so as to form a wavelength-converting section (Patent Literature 1).

Further, as a method for molding thermosetting resin, there is a method in which the thermosetting resin is molded with the use of a device that is arranged such that a movable runner bush (whose temperature is controllable) can be kept apart from a cavity in which the thermosetting resin is filled, so that the movable runner bush can be insulated from heat in thermal curing of the thermosetting resin filled in the cavity (Patent Literature 2).

Moreover, there is a method in which a primer is provided between a substrate and silicone resin for sealing a chip die-bonded onto the substrate so that bonding strength between the substrate and the silicone resin is improved (Patent Literature 3).

### Citation List

Patent Literature 1

Japanese Patent Application Publication, Tokukai, No. 2007-332259 A (Publication Date: Dec. 27, 2007)

Patent Literature 2

Japanese Patent Application Publication, Tokukai, No. 2004-58647 A (Publication Date: Feb. 26, 2004)

Patent Literature 3

Japanese Patent Application Publication, Tokukai, No. 2006-253398 A (Publication Date: Sep. 21, 2006)

### SUMMARY OF INVENTION

Technical Problem

One of characteristics required for light-emitting device production is that limit-emitting devices can be produced without much variation in color of light they emit.

An injection-molding device includes: a cavity section for providing a shape to a molded product; and a runner section in which sealing resin is retained and via which the sealing resin is injected into the cavity section. Meanwhile, thermosetting resin such as silicone resin has such a property that its viscosity is high at a room temperature but decreases as the temperature increases and the thermosetting resin cures drastically at a certain temperature.

For this reason, in a case where the sealing resin is thermosetting resin such as silicone resin and a temperature in the runner section is comparatively high, (i) sedimentation of the fluorescent material is facilitated while the sealing resin of low viscosity is retained in the runner section, and (ii) the thermosetting resin will be cured for various curing times. The sedimentation of the fluorescent material disturbs uniform dispersion of the fluorescent material. The variation in curing time causes variation in color of light the light-emitting devices emit, because the variation in curing time leads to difference in sedimentation degree of the fluorescent material.

Solution to Problem

A method of the present invention for producing a light-emitting device includes the steps of: (a) die-bonding a chip onto a substrate so as to prepare a die-bonded substrate; (b) applying a primer to the die-bonded substrate so as to prepare a primer-applied substrate; (c) preparing a mold having a cavity; (d) setting the die-bonded substrate such that the chip is placed in the cavity, and causing a base mold of the mold Lo contact with a cavity mold of the mold; (e) dispersing a fluorescent material in silicone resin so as to prepare a fluorescent material-containing sealing resin; and (f) injecting the fluorescent material-containing sealing resin into the cavity via a runner section, the runner section being capable of maintaining its temperature at a low temperature lower than a temperature of the mold, and the step (f) injecting the fluorescent-material-containing sealing resin that is maintained at the low temperature in the runner section, into the cavity via the runner section.

Advantageous Effects of Invention

The production method of the present invention makes it possible to perform resin sealing with sealing resin in which a fluorescent material is kept uniformly dispersed, thereby making it possible to produce the light-emitting devices without much variation in color of the light they emit.

### BRIEF DESCRIPTION OF DRAWINGS

FIG. 1

(a) of FIG. 1 is a perspective view illustrating a light-emitting device according to a first embodiment of the present invention and (b) of FIG. 1 is a cross-sectional view illustrating the light-emitting device according to the first embodiment of the present invention, taken along line A-A′ of (a) of FIG. 1.

FIG. 2

(a) through (d) of FIG. 2 are cross-sectional views each illustrating an arrangement of a molding device and how it operates.

FIG. 3

FIG. 3 shows how the light-emitting device according to the first embodiment of the present invention is produced.

FIG. 4

FIG. 4 illustrates a relationship between viscosity and temperature of silicone resin.

FIG. 5

FIG. 5 illustrates how sealing resin temperature and cavity temperature change over time.

FIG. 6

(a) of FIG. 6 is a perspective view illustrating a light-emitting device according to a second embodiment of the present invention and (b) of FIG. 6 is a cross-sectional view illustrating the light-emitting device according to the second embodiment of the present invention, taken along line A-A′ of (a) of FIG. 6.

FIG. 7

FIG. 7 shows how the light-emitting device according to the second embodiment of the present invention is produced.

FIG. 8

(a) and (b) of FIG. 8 are outline views each illustrating a light-emitting device according to a third embodiment of the present invention.

FIG. 9

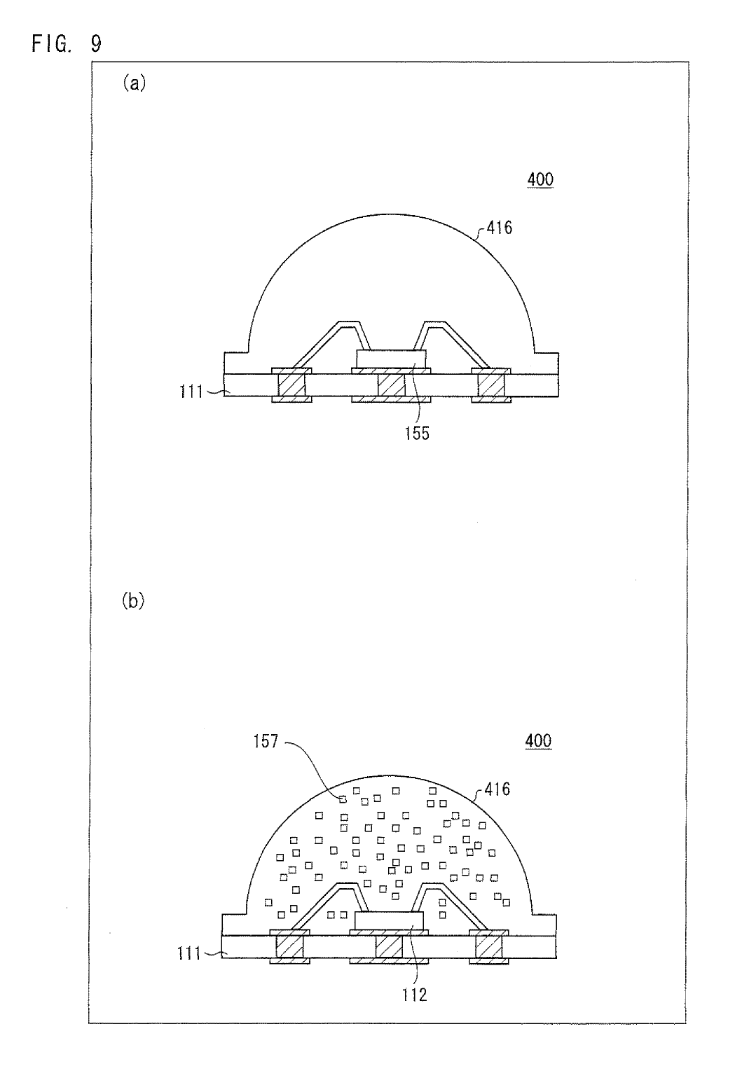

(a) and (b) of FIG. 9 are outline views each illustrating a light-emitting device according to a fourth embodiment of the present invention.

### DESCRIPTION OF EMBODIMENTS

### First Embodiment

(Light-Emitting Device)

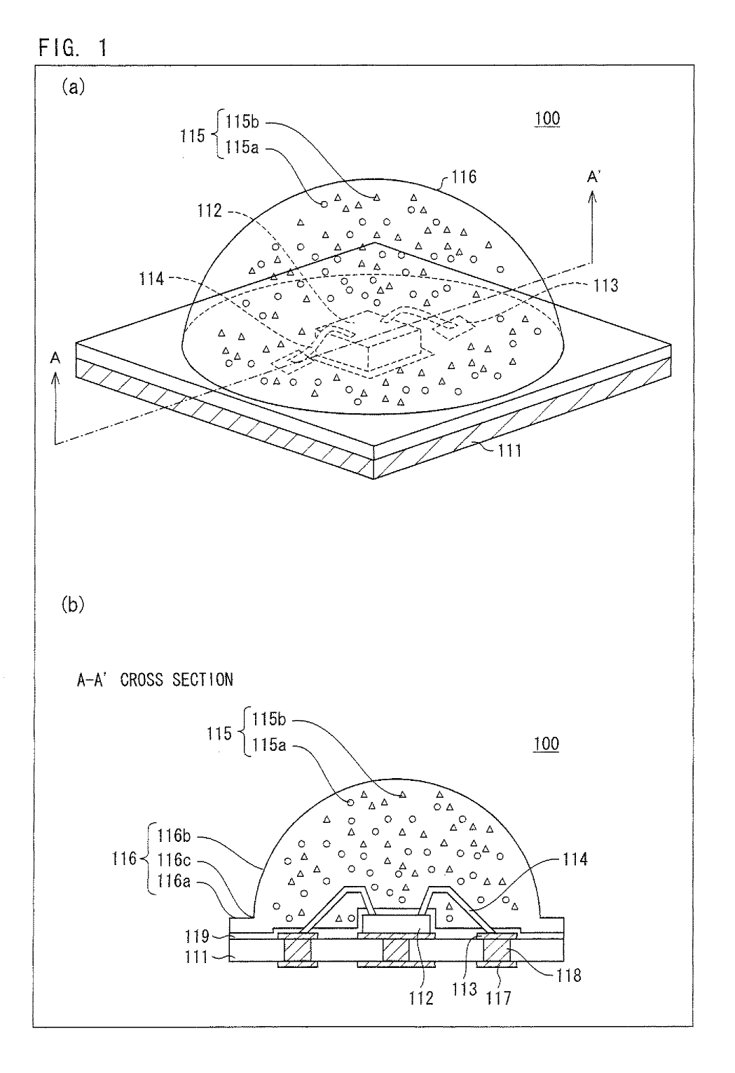

FIG. 1 is an outline view illustrating a light-emitting device according to a first embodiment of the present invention. A light-emitting device 100 includes: a substrate 111 having, for example, a dimension of 3.2 mm squares and a thickness of 0.6 mm; a chip 112 that is die-bonded onto the substrate 111; a wire 114 for connecting the chip 112 to a wiring line 113; and sealing resin 116 covering these members. A fluorescent material 115 is dispersed in the sealing resin 116 in advance so that the sealing resin 116 serves as a wavelength-converting section.

In the following description, a wavelength-converting section and after-mentioned fluorescent material-containing resin, outer layer, and transparent resin may be referred to as the sealing resin as needed.

The sealing resin 116 has such a shape having a planar part 116a provided on the substrate 111, and a hemispherical dome part 116b which is raised at a center portion of the planar part 116a and which has a diameter of 3.1 mm, for example.

In the light-emitting device 100, the chip 112 emits first-order light and the fluorescent material 115 emits second-order light by absorbing part of the first-order light traveling in the wavelength-converting section. The first-order light and the second-order light are mixed so that the light-emitting device 100 generates white outgoing light.

The chip 112 has a structure in which a semiconductor layer including a light-emitting layer is provided on a substrate made of sapphire, GaN, SiC, or the like. The chip 112 is a nitride semiconductor light-emitting element that emits first-order light that is blue light having an emission peak wavelength of about 450 nm.

The substrate 111 includes: a wiring line 113 for electrifying the chip 112, the wiring line 113 being provided on a surface of the substrate 111 on which surface the chip 112 is to be die-bonded; and an external electrode 117 for supplying an electric power to the chip 112 from the outside, the external electrode 117 being provided on the other surface of the substrate 111. The wiring line 113 is electrically connected to the external electrode 117 through a via 118. The substrate 111 is preferably arranged such that the chip 112 is die-bonded above the via 118 so that heat generated from the chip 112 is released to the outside through the via 118.

The substrate 111 requires high heat conductivity so as to promptly release heat generated while the chip 112 is being electrified. On this account, the substrate 111 is favorably made of a highly heat-releasing material, such as ceramics like almina. Especially, an LTCC (low temperature co-fired ceramic) substrate is more preferably used as the substrate 111 because its contraction is low when the substrate is fired and therefore its finished dimension is more precise, thereby improving accuracy in positioning of the substrate 111 with respect to the after-mentioned cavity.

The LTCC substrate may be, for example, one prepared in such a manner that: (i) a mixture containing ceramic powder, glass powder and organic binder made from acrylic resin is dispersed in toluene or the like solvent, shaped in a sheet-like form, and then dried so as to obtain a green sheet; and (ii) the green sheet thus obtained is laminated, subjected to thermo compression bonding, and then fired. Further, an exemplary method for forming the via 118, the wiring line 113, and the external electrode 117 with conductivity and a heat-releasing property is such that: the green sheet is holed at a position at which a via is to be formed; silver paste or the like is filled into the hole; the resulting green sheet is laminated so as to obtain a laminate; and a metal film made from silver or the like is deposited, by plating, on a position, in the laminate, at which an electrode is to be formed.

Silicone resin having high light resistance is preferably used as the sealing resin 116. The fluorescent material 115 that absorbs the first-order light and emits the second-order light having a wavelength different from that of the first-order light is dispersed in the sealing resin 116 in advance, with the result that the sealing resin 116 serves as a wavelength-converting section. The fluorescent material 115 to be used may be a mixture of: Eu-activated β-sialon as a green fluorescent material 115a that absorbs the first-order light and emits green second-order light (having an emission peak wavelength of not less than 500 nm but not more than 550 nm); and CaAlSiN₃:Eu as a red fluorescent material 115b that absorbs the first-order light and emits red second-order light (having an emission peak wavelength of not less than 600 nm but not more than 780 nm). As such, the wavelength-converting section may contain at least two types of fluorescent materials, thereby making it possible to obtain a light-emitting device having a high color rendering property. Further, with the production method of the present embodiment, it is possible to cure resin in which at least two types of fluorescent materials are evenly dispersed. As a result, the method can be preferably used for producing a light-emitting device using at least two types of fluorescent materials.

It is also possible to use a yellow fluorescent material that emits yellow light (having an emission peak wavelength of around 560 nm) as the second-order light, and such a yellow fluorescent material may be, for example, Ce:YAG (cerium-activated yttrium aluminum garnet), BOSE (Ba, Sr, O, Eu), Eu-activated α-sialon, or the like. In this case, it is possible to obtain a so-called pseudo white light-emitting element due to mixture of the blue first-order light and the yellow second-order light. The yellow fluorescent material also contains a green component and a red component in addition to the yellow component.

It is also possible to use a chip that emits UV light as the first-order light, instead of the chip 112 that emits blue light as the first-order light. In this case, the chip that emits UV light is used in combination with fluorescent materials that absorb the first-order light and emit red, green, and blue light respectively as the second-order light.

In the light-emitting device including such a wavelength-converting section in which a fluorescent material is dispersed, the percentage of the first-order light to be converted into the second-order light while the first-order light travels through the wavelength-converting section is proportional to a travel distance of the first-order light in the wavelength-converting section and concentration of the fluorescent material dispersed in a traveling path of the first-order light.

On this account, in order to reduce emission angle dependence of a spectral distribution of emitted light of the light-emitting device 100, that is, in order to reduce unevenness in color, it is preferable that travel distances of the first-order light in the wavelength-converting section become equal in all directions. Further, it is preferable that the fluorescent material be evenly dispersed. In this regard, the production method of the present embodiment allows the fluorescent material to be more evenly dispersed, as compared with a conventional technique.

In the production method of the present embodiment, a center of the hemispherical dome 116b serving as the wavelength-converting section is positioned rightly at a center point of a light-emitting layer of the chip 112 die-bonded onto the substrate 111. Further, as described later, the sealing resin is molded by use of a molding device arranged such that a runner section serving as a pathway via which the sealing resin is injected can be maintained at a low temperature. This allows the fluorescent material 115 to be evenly dispersed in the wavelength-converting section. As a result, the emission angle dependence of the spectral distribution of emitted light can be reduced and the light-emitting devices can be produced without much variation in color of the light they emit.

(Molding Method)

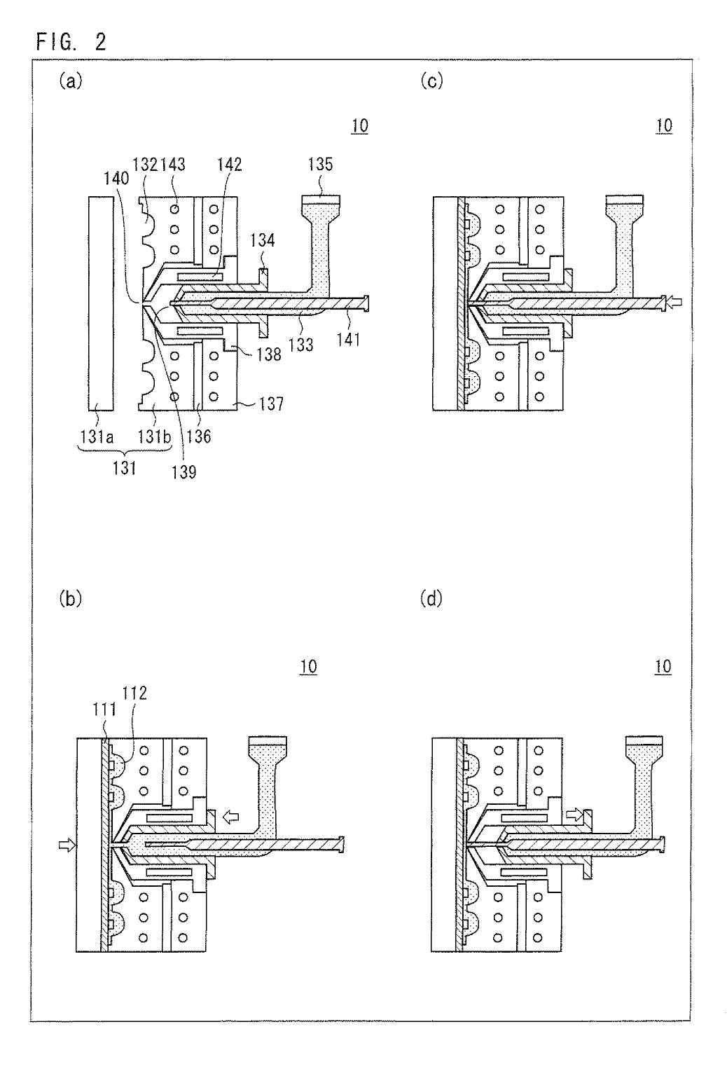

Initially explained is an arrangement of a molding device. (a) through (d) of FIG. 2 are cross-sectional views each illustrating an arrangement of a molding device 10 and how it operates.

The molding device 10 includes: a mold 131 constituted by a pair of molds, which can form a cavity by a base mold 131a as one of the molds and a cavity mold 131b as the other one of the molds; and a movable runner bush 134 including a runner section 133 via which sealing resin is injected into the cavity. One end of the runner section 133 is connected to a pouring section 135 from which the sealing resin is poured into the runner section 13.

A heat-insulating plate 136 and a back plate 137 are provided on the cavity mold 131b so as to overlap each other, and a temperature-controlling bush 138 is provided so as to penetrate through the cavity mold 131b, the heat-insulating plate 136, and the back plate 137. Further, a gate 140 is provided in the cavity 131b and the temperature-controlling bush 138, as an injection hole via which the sealing resin is injected.

The movable runner bush 134 includes a cone-shaped head, and a central hole 139 is formed on top of the cone-shaped head.

In the temperature-controlling bush 138, the movable runner bush 134 is slidably provided in such a manner that the movable runner bush 134 is caused to move back and forth by a driving device (not shown) so as to cause the central hole 139 to come into contact with or to be distanced away from the gate 140 as needed.

The cavity mold 131b includes: a recess having a cone-shaped bottom that receives the cone-shaped head of the movable runner bush 134; and the gate 140. In the arrangement, when the central hole 139 of the movable runner bush 134 contacts with the gate 140, the runner section 133 is communicated with the cavity, thereby allowing injection of the sealing resin into the cavity. Further, a valve pin 141 is provided in a movable manner in an axial direction of the movable runner bush 134. The valve pin 141 is caused to move back and forth by a driving device (not shown) so that the valve pin 141 passes through the central hole 139 of the movable runner bush 134. This arrangement allows the gate 140 to be opened or closed.

When the cavity mold 131b is distanced apart from the movable runner bush 134, the movable runner bush 134 is insulated from heat, thereby restraining that the runner section 133 in which the sealing resin is retained receives the heat of the cavity mold 131b.

The temperature-controlling bush 138 includes temperature-controlling means 142 having a hole that leads to the back plate 137 and allows temperature-controlling fluid to pass therethrough, thereby maintaining flowable sealing resin in a low temperature state as described later. Further, the cavity mold 131b includes a heating device 143 for the thermal curing.

The following describes how the molding device 10 operates and functions. As illustrated in (a) of FIG. 2, the movable runner bush 134 and the valve pin 141 are initially set back and the top of the valve pin 141 passes through the central hole 139 of the movable runner bush 134 so that a valve is close. Further, the base mold 131a, which is one of the pair of molds that is provided movable, is initially set back so that a cavity is opened and no cavity is formed. At the time, the sealing resin in a flowable state has been retained beforehand in the runner section 133. On the other hand, the movable runner bush 134 is distanced apart from the gate 140 so as to be insulated from the heat, thereby avoiding that the runner section 133 in which the sealing resin is retained receives heat of the cavity mold 131b.

Subsequently, as illustrated in (b) of FIG. 2, the substrate 111 onto which the chip 112 is die-bonded is placed in the mold 131, and the base 131a moves forward so as to contact with the cavity mold 131b, which is the other one of the pair of molds that is provided unmovable, so that the cavity is formed. At the same time, the movable runner bush 134 moves forward so that the central hole 139 contacts with the gate 140 and the runner section 133 is communicated with the cavity. In this state, the top of the valve pin 141 is not inserted into the gate 140 and the valve is open, thereby causing the sealing resin in the runner section 133 to be injected into the cavity.

Then, as illustrated in (c) of FIG. 2, after the injection of the sealing resin into the cavity is completed, the valve pin 141 moves forward so as to be inserted into the gate 140, thereby closing the valve.

Finally, as illustrated in (d) of FIG. 2, the movable runner bush 134 moves backward, and the sealing resin in the cavity is cured by heat by the heating device 143. After that, the cavity is opened up, and an obtained light-emitting device that is sealed by resin is taken out in a manner generally carried out. The valve pin 141 moves backward while the resin is being cured by heat, and is set to its initial state.

According to (a) of FIG. 2 through (d) of FIG. 2, the molding device 10 is arranged such that a surface on which the cavity section 132 is provided is along a vertical direction and the movable runner bush 134 moves in a horizontal direction. However, the molding device 10 may be rotated in such a manner that the surface on which the cavity section 132 is provided is along the horizontal direction and the movable runner bush 134 moves in the vertical direction.

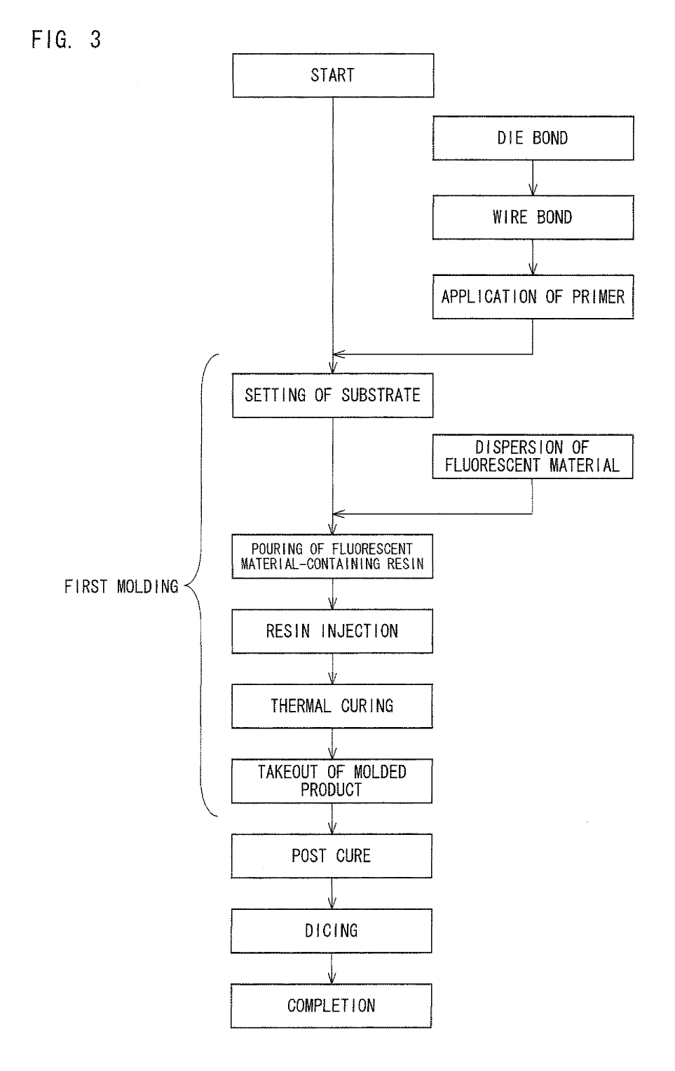

Next explained is how the light-emitting device is produced. FIG. 3 shows how a light-emitting device 100 is produced according to the first embodiment of the present invention.

The chip 112 is die-bonded onto the substrate 111, and the wiring line 113 of the substrate 111 is wire-bonded to an electrode of the chip 112 so that the wiring line 113 is electrically connected to the electrode of the chip 112. Then, a primer 119 is applied to a side of the substrate 111 to which side the chip 112 has been die-bonded. Thus, a primer-applied substrate is prepared.

The primer 119 is provided between the sealing resin 116 and the substrate 111 in order to increase bonding strength between the sealing resin 116 and the substrate 111.

The primer 119 turns yellow due to irradiation of the first-order light, which would cause a decrease in an amount of emitted light. On this account, it is preferable that the primer 119 be uniformly applied so as to have such a thin thickness that the decrease in the amount of emitted light is restrained. Examples of a method for applying the primer 119 encompass: a method in which the primer 119 is atomized and sprayed to the substrate 111; and a method in which the primer 119 is dropped onto the substrate 111 by a dispenser and the substrate 111 is spin-coated with the primer 119. These methods allow the primer 119 to be applied with a thickness of around 0.01 μm to 100 μm.

The fluorescent material 115 absorbs the first-order light and emits the second-order light, and includes the green fluorescent material 115a that emits, as the second-order light, green light having a wavelength around 540 nm and a red fluorescent material 115b that emits, as the second-order light, red light having a wave length of around 650 nm.

Subsequently, the fluorescent-material containing resin is poured from the pouring section 135 of the molding device 10 and the primer-applied substrate is placed between the cavity mold 131b and the base mold 131a. Then, the resin sealing is carried out by the aforementioned molding method. It is preferable that when the primer-applied substrate is placed between the cavity mold 131b and the base mold 131a, the chip 112 be completely in the cavity section 132 and the chip 112 be positioned concentrically with the hemispherical dome 116b.

The fluorescent-material-containing resin is poured via the pouring section 135 and retained in the runner section 133. The runner section 133 is maintained at a low temperature as described later, by the temperature-controlling means 142, so that the resin is kept flowable and highly viscose. Further, the runner section 133 is distanced apart from the cavity mold 131b after the sealing resin is injected, so that the runner section 133 is insulated from the heat of the cavity mold 131b and an increase in the temperature of the runner section 133 is restrained.

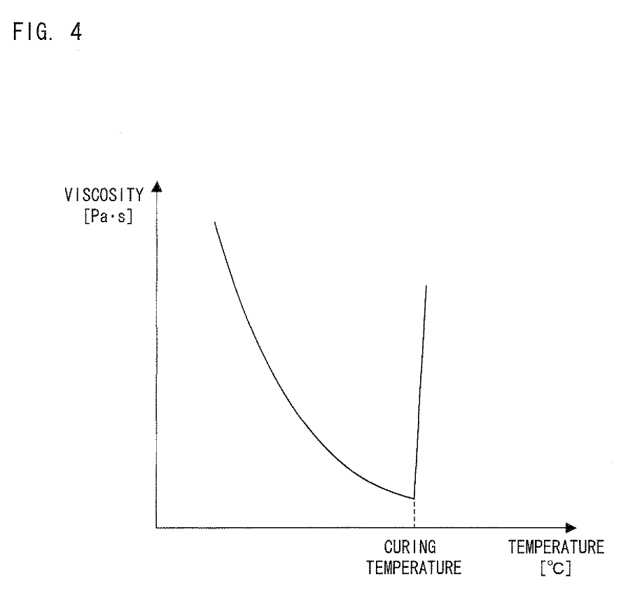

The following describes the temperature of the runner section 133 and a curing condition of the sealing resin. FIG. 4 shows a relationship between viscosity and temperature of silicone resin. The silicone resin is thermosetting resin. The viscosity of the resin is high at a low temperature but decreases as the temperature increases, and the resin drastically cures at a certain temperature. On this account, by maintaining the runner section 133 at a low temperature, it is possible to keep the resin flowable and highly viscose.

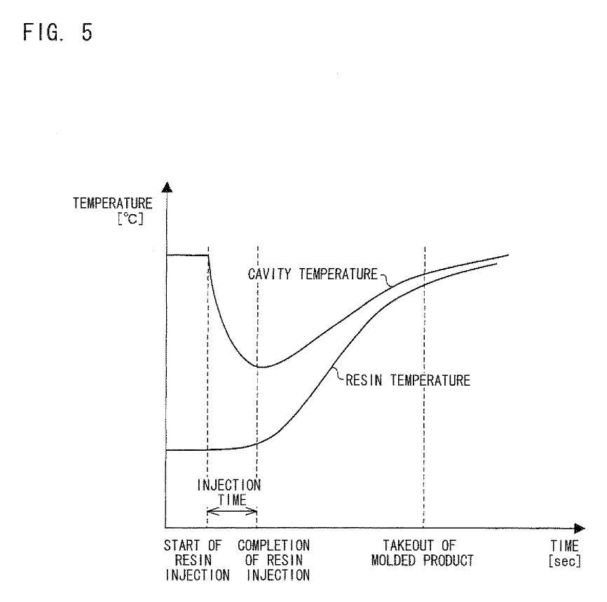

FIG. 5 shows how sealing resin temperature and cavity temperature change over time. The cavity temperature is initially maintained high and once decreases due to the injection of the low-temperature sealing resin. Then, the cavity temperature gradually increases and reaches the same temperature as the initial temperature that the cavity has before the injection of the sealing resin. On the other hand, after the sealing resin is injected into the cavity, the temperature of the sealing resin gradually increases so as to reach the cavity temperature, thereby resulting in that the sealing resin cures by the time a molded product is taken out of the molding device.

The sealing resin temporarily becomes in a low-viscosity state while the temperature of the resin is increased by the cavity mold 131b. However, a period of the low-viscosity state is extremely short and the resin cures before sedimentation of the fluorescent material 115 proceeds. As a result, it is possible to maintain uniformity in dispersion of the fluorescent material 115.

Especially in a case where several types of fluorescent materials each having a different sedimentation speed are dispersed in the sealing resin, sedimentation of each of the fluorescent materials is restrained, thereby allowing a decrease in unevenness in color caused due to uneven dispersion of the fluorescent materials. Further, concentrations of the fluorescent materials in individual light-emitting devices produced in the aforementioned manner are substantially equal to each other, thereby allowing producing the light-emitting devices without much variation in color of the light they emit.

An exemplary molding condition is as follows: a temperature of the cavity into which the sealing resin has not been injected yet is 120° C.; a temperature of the runner section 133 is 20° C.; a sealing-resin injecting time is 1 sec; and a time from completion of the resin injection to takeout of a molded product is 150 sec. As such, the resin cures at short periods, thereby making it possible to reduce sedimentation of the fluorescent material during curing of the resin.

In the production method of the present embodiment, the sealing resin is kept high viscose and the sealing resin cures at short periods. As a result, it is possible to restrain sedimentation of the fluorescent material 115. Further, since the sealing resin is highly releasable, it is not necessary that the cavity mold 131b be provided with a mold-releasing agent and production can be more easily carried out. Consequently, it is possible to reduce production costs. Moreover, the wavelength-converting section is solidly bonded to the substrate 111 via the primer 119, thereby preventing that the wavelength-converting section is removed from the substrate 111.

Since the method according to the present embodiment for producing a light-emitting device does not require a mold-releasing agent, it is possible to more faithfully reflect the shape of the cavity to the shape of the wavelength-converting section. For example, as illustrated in (b) of FIG. 1, a border part between the planar part 116a and a hem part 116c of the hemispherical dome 116b exhibits an L-shaped form in a longitudinal section of the light-emitting device 100.

After the cavity is opened and the light-emitting device sealed by the resin is taken out from the molding device, the light-emitting device is subjected to post cure. The post cure is a process for promoting curing of sealing resin by leaving a molded product to stand at a temperature (second temperature) higher than the temperature (first temperature) of the thermal curing to which the sealing resin has been subjected. A condition of the post cure is, for example, such that the temperature of the atmosphere is 150° C. and a time for leaving the molded product to stand in the atmosphere is 3 hours. Finally, the molded product is separated into individual light-emitting devices by dicing.

The production device of a light-emitting device, according to the present embodiment, is arranged such that the runner section can be insulated from the heat of the cavity section and temperatures of the runner section maintained in a low-temperature state and of the cavity section maintained in a high-temperature state can be controlled independently from each other. The period during which the cavity section contacts with the runner section and the heat is conducted from the cavity section to the runner section is limited to a period required to inject the sealing resin into the cavity. On this account, a temperature increase in the runner section and a temperature decrease in the cavity section each caused during the period are subtle. For this reason, a cycle from the setting process of a substrate to the takeout process of a molded product can be continuously carried out, thereby easily attaining a short process period.

In the present embodiment, needless to say, the post cure can be continuously carried out in the cavity before the molded product is taken out from the production device.

Further, in order that mixing of light may be promoted or sedimentation of the fluorescent material 115 may be further restrained, particles of silica or the like may be dispersed in the sealing resin.

Moreover, the light-emitting device can be also arranged such that no fluorescent material 115 is dispersed in the sealing resin so that emitted light from the chip 112 passes through the sealing resin 116 to the outside in such a manner that the wavelength of the emitted light is not converted. Further, the shape of the sealing resin 116 is not limited to the hemispherical dome shape, and can be, for example, a cubic shape, a truncated pyramid shape, a truncated cone shape, or the like shape as long as the sealing resin having such a shape can be removed from the mold 131.

### Second Embodiment

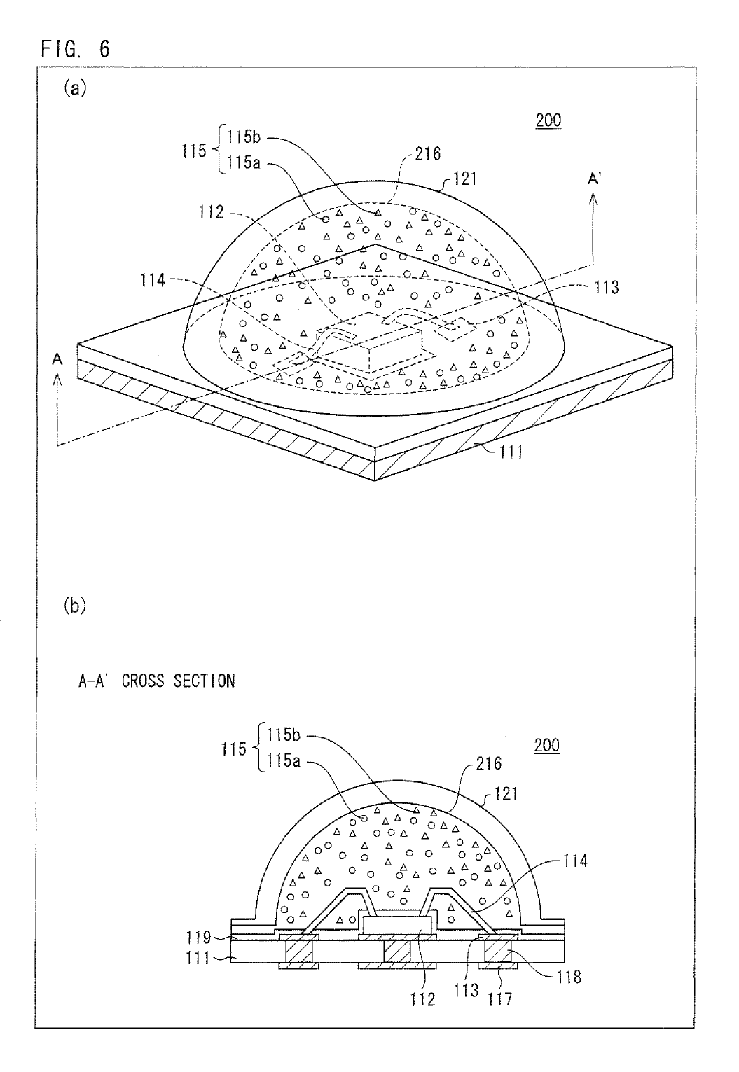

FIG. 6 is an outline view illustrating a light-emitting device according to a second embodiment of the present invention. In the present embodiment, a wavelength-converting section 216 of a light-emitting device that is produced in the same manner as in the first embodiment is covered with a transparent outer layer 121. The outer layer 121 is formed by second molding of transparent resin.

In the following description, the process from the setting of a substrate to the takeout of a molded product is referred to as first molding, and a molded product produced by the first molding is referred to as a first molded product. Further, a process from setting of the first molded product to takeout of a molded product, that is, a process of covering, with the outer layer 121, the wavelength-converting section 216 formed by the first molding is referred to as second molding.

The following describes an arrangement of a light-emitting device 200 and how it is produced. The second molding performs the same injection molding as in the first molding explained in the first embodiment. For this reason, the following only describes different points from the process in Embodiment 1.

A first different point is a dimension of the cavity section 132. A cavity section 132 for forming the outer layer 121 in the second molding has a hemispherical dome shape, similarly to that in the first molding, and is arranged such that a center point of the cavity section 132 is positioned right at a center point of the wavelength-converting section 216 formed in the hemispherical dome shape, so that the wavelength-converting section 216 is covered with the outer layer 121 formed by the second molding with uniform thickness.

A second different point is that the first molding, the second molding, and the post cure are sequentially carried out in this order. That is, the post cure is not carried out between the first molding and the second molding. The sealing resin remains in a so-called semi-cured state after the sealing resin is subjected to the thermal curing in the first molding. Then, after the second molding has been carried out, the post cure is carried out in such a manner that an obtained molded product is left to stand at a temperature (second temperature) higher than the temperature (first temperature) of the thermal curing to which the sealing resin has been subjected, thereby allowing the sealing resin to be completely cured.

This makes it possible to maintain the shape of the wavelength-converting section 216 and the dispersion state of the fluorescent material 115, and to adhere the wavelength-converting section 216 to the outer layer 121.

In order that the wavelength-covering section 216 may be solidly adhered to the outer layer 121, a material of transparent resin for the outer layer 121 is preferably silicone resin, similarly to the first molding. Further, it is also possible to use, as the transparent resin, epoxy resin or the like material different from that of the wavelength-converting section 216. However, in this case, a primer may be applied between the wavelength-converting section 216 and the outer layer 121 so that bonding strength between them increases.

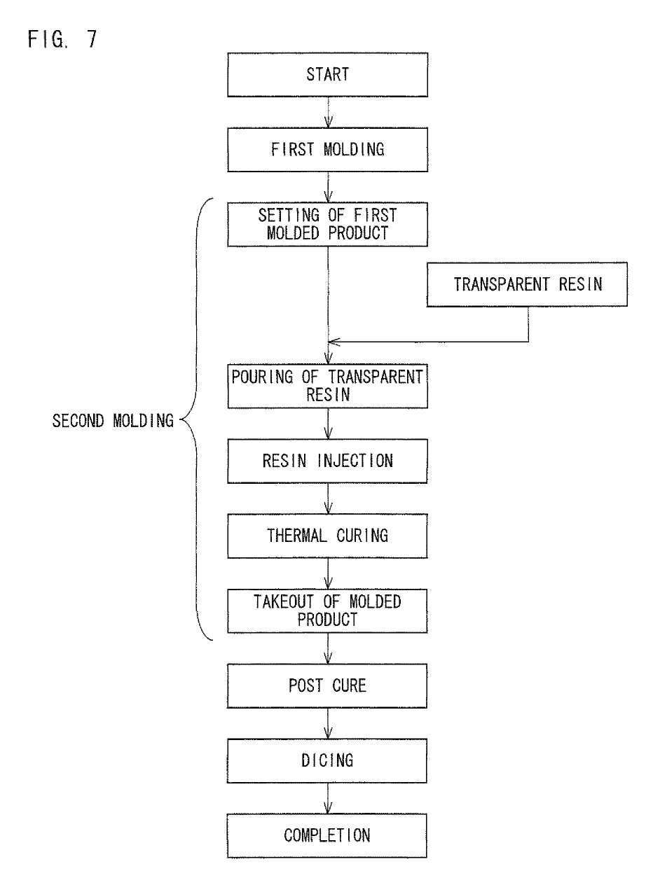

FIG. 7 shows how the light-emitting device according to the second embodiment of the present invention is produced. In the second molding, transparent resin is poured from a pouring section 135 of a molding device 10 and a first-molded product is placed between a cavity mold 131b and a base mold 131a. Then, the second molding is carried out by the same method as the aforementioned molding method. Subsequently, the cavity is opened and a second-molded product is taken out from the molding device 10. The second-molded product is then post-cured, and finally, the second-molded product thus post-cured is diced into individual light-emitting devices.

A molding condition is, for example, set in the same manner as in the first embodiment such that: temperatures, in the first and second moldings, that the cavity has before the injection of the sealing resin are 120° C.; a temperature of the runner section 133 is 20° C.; a sealing-resin injecting time is 1 see; and a time from completion of the resin injection to the takeout of a molded product is 150 sec. The post cure is carried out under a condition in which a temperature of the atmosphere is 150° C. and a time for leaving a molded product to stand in the atmosphere is 3 hours, which is the same as in the first embodiment.

With the production method of the present embodiment, it is possible to independently control the material and the shape of the wavelength-converting section 216, the composition of the fluorescent material 115, and the composition and the shape of the outer layer 121. That is, a color level of emitted light can be controlled by the shape of the wavelength-converting section 216, the composition of the fluorescent material 115, and the like. Further, optical functions such as collection and diffusion of light can be controlled by the shape and material of the outer layer 121 and adjustment of refractivity.

In the present embodiment, needless to say, the post cure can be continuously carried out in the cavity by increasing the temperature of the cavity, after the second molding has been carried out but before the molded product is taken out from the molding device.

### Third Embodiment

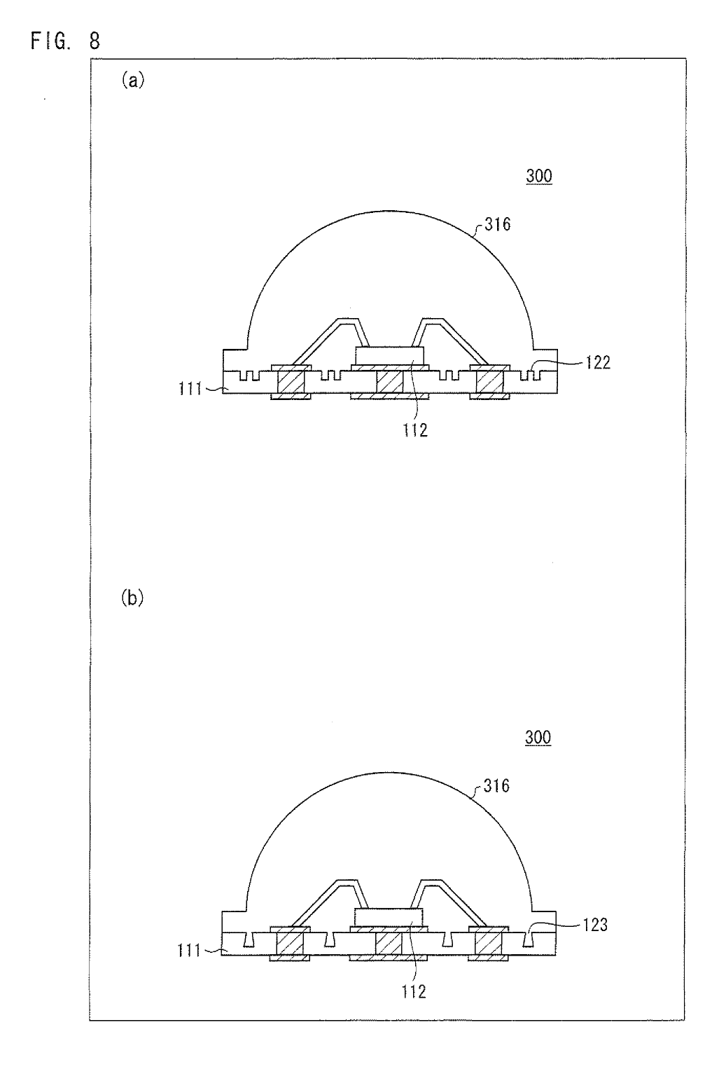

FIG. 8 is an outline view of a light-emitting device according to a third embodiment of the present invention. The present embodiment has the following remarkable feature. That is, the light-emitting device is arranged such that either a roughened surface portion 122 or a recess portion 123 is initially provided on a surface of a substrate 111 on which surface a chip 112 is to be die-bonded, and a part of sealing resin 316 is embedded in the roughened surface portion 122 or the recess portion 123. In this arrangement, the sealing resin 316 is solidly bonded to the substrate 111 due to an anchor effect.

In the present embodiment, the sealing resin 316 is directly bonded to the substrate 111, and no primer 119 is applied between them. However, needless to say, the primer 119 may be applied between them. Further, it is not a big problem whether or not the recess section 123 may penetrate through the substrate 111.

A method for forming the roughened surface portion 122 or the recess portion 123 on the substrate 111 is, for example, a method in which, in a production process of the substrate 111, a green sheet is holed at a part where the roughened surface portion 122 or the recess portion 123 is to be formed, and the green sheet is laminated.

The method according to the present embodiment for producing the light-emitting device 300 can be carried out in the same manner as in the first or second embodiment, except that the roughened surface portion 122 or the recess portion 123 is formed on the substrate 111.

The present embodiment can increase the bond strength between the sealing resin 116 and the substrate 111, thereby preventing that the sealing resin 116 is removed from the substrate 111.

### Embodiment 4

FIG. 9 is an outline view of a light-emitting device according to a fourth embodiment of the present invention. The present embodiment has such a remarkable feature that sealing resin 416 is directly bonded to a substrate 111 due to adhesiveness of the sealing resin. The light-emitting device of the present embodiment can be produced in the same manner as in any one of Embodiments 1 through 3, except that general liquid curable resin is used.

A light-emitting device 400 illustrated in (a) of FIG. 9 is arranged such that a chip 155 die-bonded onto a substrate 111 is covered with epoxy resin, and the chip 155 is a semiconductor light-emitting element that emits red light having an emission peak wavelength of about 650 nm. For example, in a case where the sealing resin 416 has high adhesiveness with respect to the substrate 111, like epoxy resin, it is possible to directly seal the chip 155 die-bonded onto the substrate 111 without providing a primer 119 between the sealing resin 416 and the substrate 111.

The chip 155 is not limited to one that emits red light, but may be a semiconductor light-emitting element that emits green light having an emission peak wavelength of about 550 nm. In a case where an emission wavelength of the chip to be sealed is, for example, a long wavelength of more than 520 nm, limitation of light resistance is eased. On this account, a material for the sealing resin 416 may be a general liquid curable resin, with the result that not only silicone resin but epoxy resin and the like resin can be used.

A light-emitting device 400 illustrated in (b) of FIG. 9 is arranged such that a chip 112 that emits blue light is die-bonded onto a substrate 111 and covered with silicone resin in which an adhesion auxiliary agent 157 has been preliminarily dispersed. The adhesion auxiliary agent 157 is a material dispersed in the silicone resin to increase bonding strength between the silicone resin and the substrate, and a silane coupling agent or the like is used as the adhesion auxiliary agent 157. The silicone resin itself is highly releasable with respect to the substrate 111. However, by preliminarily dispersing the adhesion auxiliary agent in the silicone resin so that the silicone resin has adhesiveness, it is possible that the silicone resin is more solidly bonded to the substrate 111.

As such, in the case where sealing resin itself has high adhesiveness or sealing resin contains an adhesion auxiliary agent so that its adhesiveness increases, it is possible to directly bond the sealing resin to the substrate without using the primer 119. In this case, the cavity mold 131b preferably includes a mold-releasing agent so that a molded product can be easily removed from the mold.

(Overview of Embodiments)

A method for producing the light-emitting device 100, 200, or 300, according to the embodiments of the present invention, includes the steps of: (a) die-bonding a chip 112 onto a substrate 111 so as to prepare a die-bonded substrate; (b) applying a primer 119 to the die-bonded substrate so as to prepare a primer-applied substrate; (c) preparing a mold 131 having a cavity; (d) setting the die-bonded substrate such that the chip 112 is placed in the cavity, and causing a base mold 131a of the mold 131 to contact with the a cavity mold 131b of the mold 131; (e) dispersing a fluorescent material 115 in silicone resin so as to prepare a fluorescent material-containing sealing resin; and (f) injecting the fluorescent material-containing sealing resin into the cavity via a runner section 133, the runner section 133 being capable of maintaining its temperature at a low temperature lower than a temperature of the mold 131, and the step (f) injecting the fluorescent material-containing sealing resin that is maintained at the low temperature in the runner section 133, into the cavity via the runner section 133.

Further, a method for producing the light-emitting device 400, according to the embodiment of the present invention, includes the steps of: (a) die-bonding a chip 155 onto a substrate 111 so as to prepare a die-bonded substrate; (b) applying a primer 199 to the die-bonded substrate so as to prepare a primer-applied substrate; (c) preparing a mold 131 having a cavity; (d) setting the die-bonded substrate such that the chip 155 is placed in the cavity, and causing a base mold 131a of the mold 131 to contact with a cavity mold 131b of the mold 131; (e) dispersing a fluorescent material 115 in silicone resin so as to prepare a fluorescent material-containing sealing resin; and (f) injecting the fluorescent material-containing sealing resin into the cavity via a runner section 133, the runner section 133 being capable of maintaining its temperature at a low temperature lower than a temperature the mold 131, and the step (f) injecting the fluorescent material-containing sealing resin that is maintained at the low temperature in the runner section 133, into the cavity via the runner section 133.

The method according to the embodiments of the present invention for producing the light-emitting device 100, 200, 300, or 400, further includes, after the step (f), the sequential steps of: (g) curing the fluorescent material-containing sealing resin by heat of a first temperature; (h) covering the fluorescent material-containing sealing resin with transparent resin; and (i) curing the transparent resin by heat of the first temperature so as to obtain a molded product. The method further includes, subsequently to the step (i), the steps of: (j) taking out the molded product from the cavity; and (k) leaving the molded product to stand at a second temperature higher than the first temperature of the thermal curing to which the fluorescent material-containing sealing resin or the transparent resin has been subjected.

The light-emitting device 200 according to the embodiment of the present invention is a light-emitting device produced by the aforementioned method, and includes: a substrate 111; a chip 112 that emits first-order light, the chip being die-bonded onto the substrate 111; and a wavelength-converting section 216 that covers the chip 112, the wavelength-converting section 216 being made of silicone resin in which a fluorescent material 115 is dispersed.

### REFERENCE SIGNS LIST

10: Molding Device

100, 200, 300, 400: Light-Emitting Device

111: Substrate

112, 155: Chip

115: Fluorescent Material

116, 316, 416: Sealing Resin

119: Primer

121: Outer Layer

122: Roughened Surface Portion

123: Recess Section

131: Mold

131a: Base Mold

131b: Cavity Mold

132: Cavity

133: Runner Section

134: Movable Runner Bush

138: Temperature-Controlling Bush

139: Central Hole

140: Gate

141: Valve Pin

142: Temperature-Controlling Means

157: Adhesion Auxiliary Agent

216: Wavelength-Converting Section

1. A method for producing a light-emitting device, comprising the steps of:
(a) die-bonding a chip onto a substrate so as to prepare a die-bonded substrate;
(b) preparing a mold having a cavity;
(c) setting the die-bonded substrate such that the chip is placed in the cavity; and
(d) injecting sealing resin into the cavity via a runner section,
the runner section being capable of maintaining its temperature at a low temperature lower than a temperature of the mold, and
the step (d) injecting the sealing resin that is maintained at the low temperature in the runner section, into the cavity via the runner section.

2. The method as set forth in claim 1, wherein the sealing resin contains a fluorescent material dispersed therein.

3. The method as set forth in claim 2, further comprising, after the step (d), the step of covering the sealing resin with an outer layer made of transparent resin.

4. The method as set forth in claim 1, wherein the sealing resin is silicone resin.

5. The method as set forth in claim 3, wherein the sealing resin is silicone resin.

6. The method as set forth in claim 1, further comprising the step of applying a primer to the substrate.

7. The method as set forth in claim 5, further comprising the step of applying a primer to the substrate.

8. The method as set forth in claim 1, wherein the sealing resin contains at least two types of fluorescent materials dispersed therein.

9. The method as set forth in claim 7, wherein the sealing resin contains at least two types of fluorescent materials dispersed therein.

10. The method as set forth in claim 1, wherein the substrate is a ceramic substrate.

11. The method as set forth in claim 97 wherein the substrate is a ceramic substrate.

12. The method as set forth in claim 1, further comprising, after the step (d), the steps of:
(e) curing the sealing resin by heat of a first temperature so as to obtain a resin-sealed light-emitting device; and
(f) post-curing the sealing resin by leaving the resin-sealed light-emitting device to stand at a second temperature that is higher than the first temperature.

13. The method as set forth in claim 11, further comprising, after the step (d), the steps of:
(g) curing the sealing resin by heat of a first temperature so as to obtain a resin-sealed light-emitting device; and
(h) post-curing the sealing resin by leaving the resin-sealed light-emitting device to stand at a second temperature that is higher than the first temperature.

14. The method as set forth in claim 1, wherein the cavity has a hemispherical dome-shaped portion.

15. The method as set forth in claim 13, wherein the cavity has a hemispherical dome-shaped portion.

16. The method as set forth in claim 1, wherein the substrate has a surface that is to be subjected to the sealing by the sealing resin and has a roughened surface portion or a recess portion on the surface.

17. The method as set forth in claim 15, wherein the substrate has a surface that is to be subjected to the sealing by the sealing resin and has a roughened surface portion or a recess portion on the surface.

18. The method as set forth in claim 1, wherein the sealing resin contains an adhesion auxiliary agent dispersed therein.

19. The method as set forth in claim 17, wherein the sealing resin contains an adhesion auxiliary agent dispersed therein.
